(19) United States
(12) Patent Application Publication
(10) Pub. No.: US 2019/0356312 A1
(43) Pub. Date: Nov. 21, 2019

(54) METHODS AND SYSTEMS FOR A CAPACITIVE HANDLE

(71) Applicant: KONINKLIJKE PHILIPS N.V., EINDHOVEN (NL)

(72) Inventors: LESTER RONALD GREER, Jr., EDMONDS, WA (US); WALTER JULIUS WEICHSLER, KIRKLAND, WA (US); MICHAEL JAMES GORGA, MONROE, WA (US)

(21) Appl. No.: 16/466,093

(22) PCT Filed: Nov. 29, 2017
(86) PCT No.: PCT/EP2017/080748

§ 371 Date: Jun. 3, 2019

Related U.S. Application Data
(60) Provisional application No. 62/428,685, filed on Dec. 1, 2016.

(51) Int. Cl. H03K 17/955

(52) U.S. Cl. CPC H03K 17/955; H03K 2217/94042; H03K 2217/94026

(57) ABSTRACT

A method (500) for activating a hand-held electronic device (10) includes the steps of: providing (510) a hand-held electronic device comprising a body portion (12) and a proximity sensor (50), wherein the proximity sensor comprises a capacitor; determining (520), via the capacitor, a baseline capacitance of the proximity sensor; detecting (530), via the capacitor, an approaching target object (52) before the target object touches the body portion, wherein the approaching target object increases capacitance of the proximity sensor to a first capacitance; comparing (540) the first capacitance to the baseline capacitance; and activating (550) the hand-held electronic device if the first capacitance exceeds the baseline capacitance.

### FIELD OF THE INVENTION

The present disclosure is directed generally to methods and systems for activation of hand-held devices in response to a change in capacitance of a proximity sensor.

### BACKGROUND

Hand-held electronic devices have been developed to facilitate various activities including communications and household activities such as home care, food preparation and personal care. These hand-held electronic devices, or electronic devices that incorporate a hand-held component having a body portion, including smart phones, kitchen appliances, home care devices, toothbrushes, flossers, shavers, skin cleaners, and many others, use power to drive moving parts such as motors or oscillators to enhance the power of the device during an operating session. The hand-held electronic devices also use power to drive one or more integrated sensors which obtain data about the operating session. This data can then be utilized to provide feedback to the user about the operation of the device, and/or to improve the functionality of the device in the same or subsequent operating sessions.

However, these hand-held electronic devices have several limitations. Most importantly, these devices can consume a great deal of power during an operating session. While it is desirable to have a device that consumes as little power as possible, these devices typically require frequent recharging in order to be ready for an operating session. As a result these hand-held electronic devices cannot be in a constant activated state, and thus require a user to actively turn on the device.

Accordingly, there is a continued need in the art for methods and devices that allow for a device that can be activated without user input, while minimizing the amount of power consumed by the device.

### SUMMARY OF THE INVENTION

The present disclosure is directed to inventive methods and systems for activation of a hand-held electronic device in response to a change in capacitance of a proximity sensor. Applied to a hand-held electronic device, the inventive methods and systems enable automatic activation of a hand-held electronic device as the user's hand approaches the device, rather than in response to direct user activation of the device. The hand-held electronic device comprises a proximity sensor that detects a change in capacitance as the user's hand approaches the device. The proximity sensor sends a signal to the device to activate in response to the change in capacitance. The hand-held electronic device also comprises a calibration mechanism configured to recalibrate the proximity sensor to a new capacitance after a predetermined amount of time, thus enabling the device to adapt to new surroundings or an environment affecting the proximity sensor. This calibration mechanism prevents the hand-held electronic device from spurious activation, thereby further preserving power.

Generally in one aspect, a method for activating a hand-held electronic device is provided. The method includes the steps of: (i) providing a hand-held electronic device comprising a body portion and a proximity sensor comprising a capacitor; (ii) determining, via the capacitor, a baseline capacitance of the proximity sensor; (iii) detecting, via the capacitor, an approaching target object before the target object touches the body portion, wherein the approaching target object increases capacitance of the proximity sensor to a first capacitance; (iv) comparing the first capacitance to the baseline capacitance; and (v) activating the hand-held electronic device if the first capacitance exceeds the baseline capacitance.

According to an embodiment, the proximity sensor comprises a conductive component configured to increase a sensitivity of the proximity sensor. According to an embodiment, the conductive component is a metal frame of the hand-held electronic device. According to an embodiment, the conductive component is an antenna of the hand-held electronic device.

According to an embodiment, the proximity sensor comprises a conductive connector configured to electrically connect a capacitor sensor to the conductive component.

According to an embodiment, the hand-held electronic device is activated before the target object touches the hand-held electronic device.

According to an embodiment, the method further includes the step of calibrating, after a predetermined period of time, the proximity sensor with a new baseline capacitance.

According to an embodiment, the method further includes the step of deactivating a calibration protocol if the hand-held electronic device is active.

According to an embodiment, the method further includes the step of comparing the first capacitance to a predetermined threshold, wherein the hand-held electronic device is activated only if the first capacitance exceeds the predetermined threshold.

According to an aspect, a hand-held electronic device, or an electronic device having a hand-held body portion is provided. The device includes: a body portion comprising a proximity sensor including a capacitor; and a controller configured to: (i) determine, via the capacitor, a baseline capacitance of the proximity sensor; (ii) detect, via the capacitor, an approaching target object before the target object touches the body portion, wherein the approaching target object increases capacitance of the proximity sensor to a first capacitance; (iii) compare the first capacitance to the baseline capacitance; and (iv) activate the hand-held electronic device if the first capacitance exceeds the baseline capacitance.

According to an aspect, a method for activating a hand-held electronic device is provided. The method includes the steps of: (i) providing a hand-held electronic device comprising a body portion and a proximity sensor, wherein the proximity sensor comprises a capacitor; (ii) determining, via the capacitor, a baseline capacitance of the proximity sensor; (iii) calibrating, after a predetermined period of time, the proximity sensor with a new baseline capacitance; (iv) detecting, via the capacitor, an approaching target object before the target object touches the body portion, wherein the approaching target object increases capacitance of the proximity sensor to a first capacitance; (v) comparing the first capacitance to the baseline capacitance; (vi) comparing the first capacitance to a predetermined threshold; and (vii) activating the hand-held electronic device if the first capacitance exceeds the predetermined threshold, wherein the hand-held electronic device is activated before the target object touches the hand-held electronic device.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

These and other aspects of the invention will be apparent from and elucidated with reference to the embodiment(s) described hereinafter.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention.

FIG. 1 is a schematic representation of a hand-held electronic device, in accordance with an embodiment.

FIG. 2 is a schematic representation of a hand-held electronic device, in accordance with an embodiment.

FIG. 3 is a schematic representation of a hand-held electronic device, in accordance with an embodiment.

FIG. 4 is a schematic representation of a hand-held electronic device, in accordance with an embodiment.

FIG. 5 is a flowchart of a method for activating a hand-held electronic device, in accordance with an embodiment.

### DETAILED DESCRIPTION OF EMBODIMENTS

The present disclosure describes various embodiments of a hand-held electronic device or an electronic device having a hand-held component with a body, comprising a proximity sensor to enable activation of the device in response to the user's hand approaching the device. More generally, Applicant has recognized and appreciated that it would be beneficial to provide a device that automatically activates as the user reaches for the device, rather than waiting for direct user activation. Accordingly, the methods and systems described or otherwise envisioned herein provide an hand-held electronic device comprising a proximity sensor that detects changes in capacitance and automatically activates the device in response to a change in capacitance that results from the user's approaching hand. According to an embodiment, the hand-held electronic device comprises a calibration mechanism configured to recalibrate the proximity sensor to a new capacitance after a predetermined amount of time, thus enabling the device to adapt to new surroundings or an environment affecting the proximity sensor.

The embodiments and implementations disclosed or otherwise envisioned herein can be utilized with any electronic device, including but not limited to personal care devices, home care devices, home appliances, and hand-held communication devices. Examples of suitable devices include an electric toothbrush, an oral irrigator, a shaver, a skin cleanser, a hand-held kitchen mixer, a smart cellular phone, or any other hand-held electronic device or electronic device having a hand-held component. However, the disclosure is not limited to these enumerated devices, and thus the disclosure and embodiments disclosed herein can encompass any electronic device.

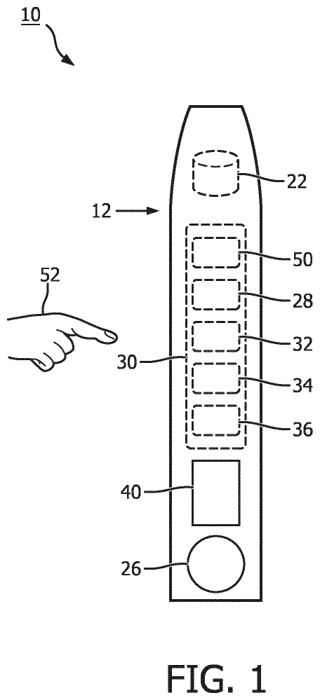

Referring to FIG. 1, in one embodiment, a hand-held electronic device 10 is provided that includes a body portion 12. According to an embodiment, body portion 12 may include a motor 22, electromagnet(s), or other drive configured to generate operation or movement of at least a portion of the device 10. For example, in the case of a toothbrush, motor 22 drives oscillation of a brush head member. In the case of a shaver, motor 22 drives oscillation of one or more blades. In the case of a kitchen appliance, motor 22 drives a device such as a mixer device, electric knife blade or other component. In other embodiments without a motor 22, hand-held electronic device 10 comprises electrical components such as a battery.

Body portion 12 can be further provided with a user input 26 to activate and deactivate the device. The user input 26 allows a user to operate the hand-held electronic device 10, for example to turn the device on and off. The user input 26 may, for example, be a button, touch screen, or switch.

According to an embodiment, hand-held electronic device 10 can comprise a controller 30. Controller 30 may be formed of one or multiple modules, and can be configured to operate the hand-held electronic device 10 in response to an input, such as input obtained via user input 26 or an input obtained from a proximity sensor, as described herein. Controller 30 can comprise, for example, at least a processor 32, a memory 34, and a connectivity module 36. The processor 32 may take any suitable form, including but not limited to a microcontroller, multiple microcontrollers, circuitry, a single processor, or plural processors. The memory 34 can take any suitable form, including a non-volatile memory and/or RAM. The non-volatile memory may include read only memory (ROM), a hard disk drive (HDD), or a solid state drive (SSD). The memory can store, among other things, an operating system. The RAM is used by the processor for the temporary storage of data. According to an embodiment, an operating system may contain code which, when executed by controller 30, controls operation of the hardware components of hand-held electronic device 10. According to an embodiment, connectivity module 36 transmits collected data, and can be any module, device, or means capable of transmitting a wired or wireless signal, including but not limited to a Wi-Fi, Bluetooth, near field communication, and/or cellular module.

According to an embodiment, hand-held electronic device 10 can comprise one or more sensors 28. Sensor 28 is shown in FIG. 1 within body portion 12, but may be located anywhere within the device. The one or more sensors may comprise, for example, an accelerometer, a gyroscope, a magnetometer, a pressure sensor, a camera, a photocell, a visible light sensor, a near-infrared sensor, a radio wave sensor, and/or any of a wide variety of other sensors configured to generate data during and/or between operating sessions. Many different types of sensors could be utilized. According to an embodiment, the sensor 28 is integral to the controller 30.

According to an embodiment, hand-held electronic device 10 can comprise a user interface 40 configured to provide information to a user before, during, and/or after an operating session. The user interface 40 can take many different forms, but is configured to provide information to a user. For example, the information can be read, viewed, heard, felt, and/or otherwise interpreted concerning the operating session. According to an embodiment, the user interface 40 provides feedback to the user, such as a guided operating session, that includes information about where and how to clean. Accordingly, the user interface may be a display that provides information to the user, a haptic mechanism that provides haptic feedback to the user, a speaker to provide sounds or words to the user, or any of a variety of other user interface mechanisms. According to an embodiment, controller 30 of hand-held electronic device 10 receives information from sensor 28, assesses and analyzes that information, and provides information that can be displayed to the user via the user interface 40.

Hand-held electronic device 10 also comprises a proximity sensor 50 configured to measure a change in capacitance when a target object 52 approaches handle 12 of device 10. Target object 52 can be a user's finger, hand, or any conductive object. According to an embodiment, the proximity sensor can be a printed circuit board (PCB) based capacitor which is formed in or printed on a nonconductive material such as PCB or glass. The capacitor structure is configured such that the generated electric field can be interfered with by the conductive target object 52.

According to an embodiment, a PCB-based capacitor is formed in or printed on the PCB, and the generated electric field is allowed to leak into the area around the capacitor. The interaction of the field generator and the surrounding area creates a baseline capacitance that can be measured. When a conductor such as target object 52 approaches the capacitor, the electric field is interfered with, causing the resulting capacitance to change from the baseline. Typically, the target object 52 increases the capacitance of the structure beyond the baseline capacitance. According to an embodiment, the capacitor continuously measures the capacitance of the sensors in the system and compares each result to a predetermined baseline capacitance. When the capacitance increases beyond the baseline and/or beyond a predetermined threshold, the system interprets the increase as the approach of the target object 52.

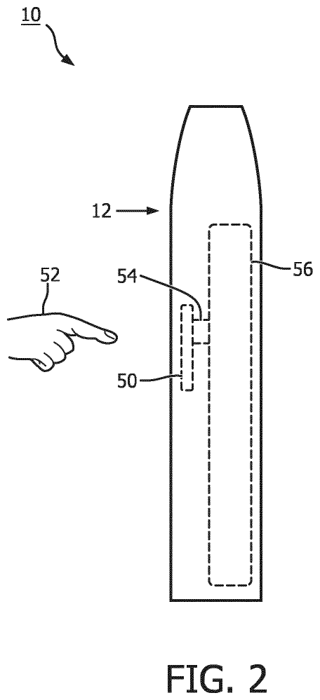

Referring to FIG. 2, in one embodiment, is a hand-held electronic device 10. The hand-held electronic device can be any of the electronic devices embodiments disclosed or otherwise envisioned herein. For example, according to an embodiment, hand-held electronic device 10 includes a controller comprising a processor and memory, a motor, user input, sensor, and/or user interface, among other elements.

Hand-held electronic device 10 comprises a proximity sensor 50 configured to measure a change in capacitance when a target object 52 approaches handle 12 of device 10, where the target object is a user's finger, hand, or any conductive object. The proximity sensor can be a PCB-based capacitor which is formed in or printed on the PCB, which could be, for example, the controller. The capacitor structure is configured such that the generated electric field can be interfered with by the conductive target object 52.

To enhance the sensitivity of the proximity sensor 50, it can be connected to one or more conductive components of the hand-held electronic device, thereby increasing the range of the capacitor's detection. For example, the proximity sensor can be a PCB-based capacitor which is formed in or printed on the PCB, and can be connected via conductive connector 54 to a conductive component 56 of the hand-held electronic device. For example, as shown in FIG. 2, the capacitor is connected by a conductive connector 54 to a metal frame 56 of or within the hand-held electronic device. The metal frame of the hand-held electronic device acts as an antenna to enhance the sensitivity of the hand-held electronic device.

According to an embodiment, conductive connector 54 can be any conductive element. For example, conductive connector 54 can be a pressure sensitive adhesive (PSA) type conductive gasket, a surface-mount technology (SMT) type conductive gasket, a pogo pin connector, or a spring finger connector, among many other connector types. Each of these connectors, for example, may be in conductive communication with: (i) the PCB or other fixed component of the proximity sensor 50; and (ii) the conductive component 56. In some embodiments of hand-held electronic device 10, it will be necessary to have some degree of freedom or motion between the proximity sensor 50 and/or conductive connector 54 and the conductive component 56, such as in devices that oscillate, vibrate, or otherwise undergo movement. Accordingly, the conductive connector 54 and/or conductive component 56 may be configured or constructed to allow the necessary movement while still enabling a conductive connection.

According to another embodiment, conductive connector 54 may not be a necessary component of the system. For example, conductive component 56 may be an integral antenna which can be integrally formed in or otherwise connected to the PCB, thereby eliminating the need for the conductive connector 54.

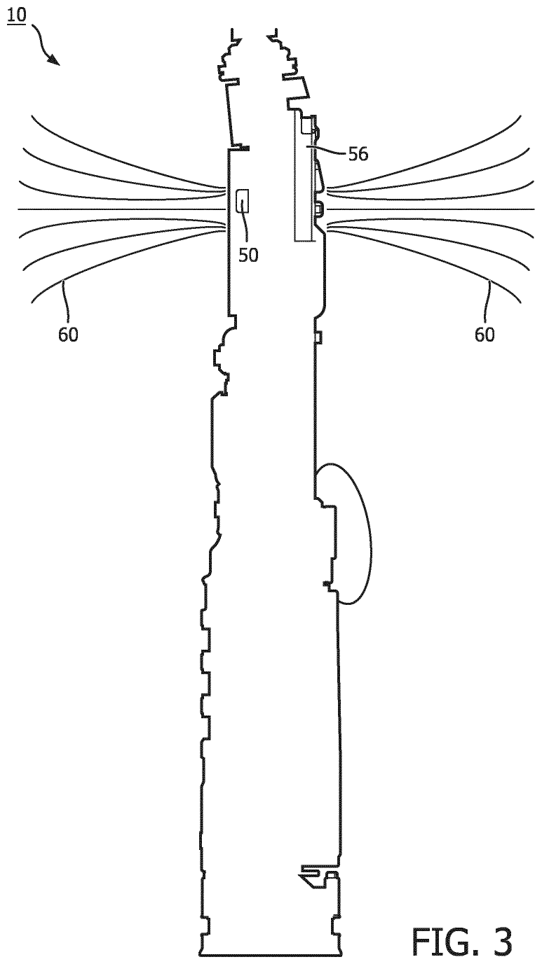

Referring to FIG. 3, in one embodiment, is a hand-held electronic device 10 comprising a proximity sensor. In this embodiment, the proximity sensor 50 is utilizing a metal frame of the device as a conductive component 56 to extend the sensitivity of the sensor. Although not visible to the naked eye, when the proximity sensor is active an electrical field with field lines 60 will emit from the device. Some of the field lines 60 will connect to ground within the device, such as the battery, the PCB, or other structure. Other of the field lines 60, however, will not connect to ground, and act as a sensing component of the capacitor, ready to respond to a target object that approaches the field. This state of the capacitor, with some of the field connected to ground and some of the field not connected to ground, is calculated as a baseline.

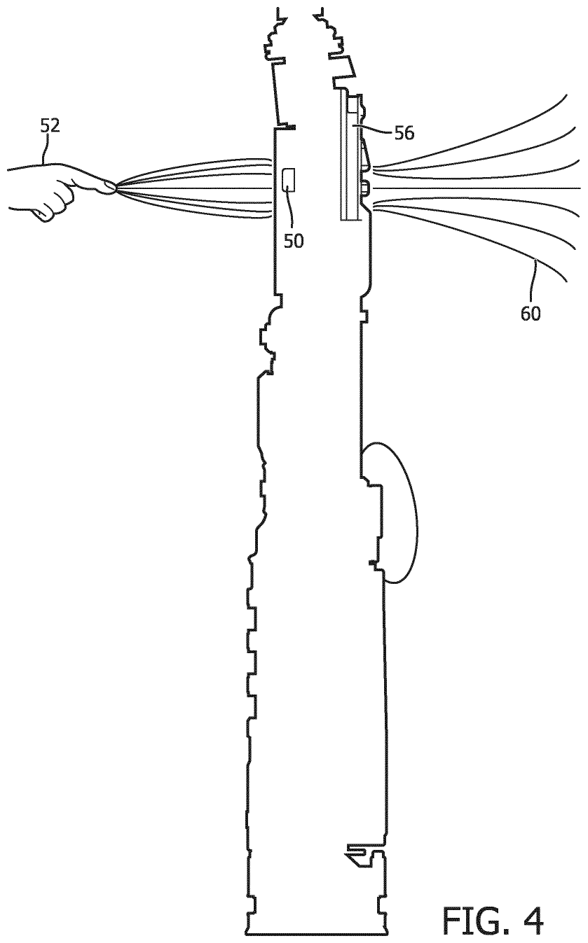

Referring to FIG. 4, in one embodiment, is the hand-held electronic device 10 of FIG. 3, in which a target object 52 is approaching the device and affecting the electrical field 60 emitted from the device. The proximity sensor 50 detects the change in capacity resulting from the target object 52 affecting the electrical field emitted from the device, and the system determines whether this is a change from the baseline, and/or whether the change exceeds a predetermined threshold. If there is a change from baseline, and/or if the change exceeds the threshold, then the system activates, as described herein.

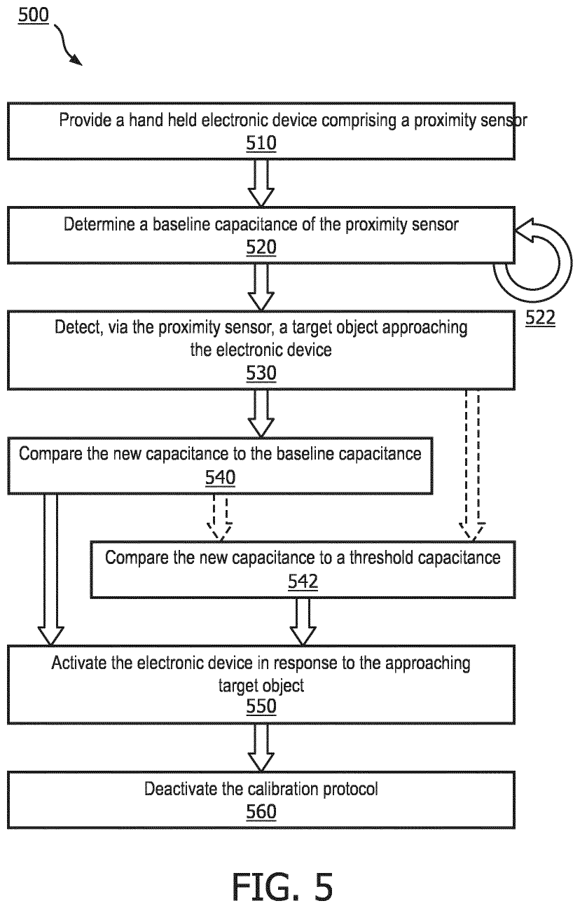

Referring to FIG. 5, in one embodiment, is a flowchart of a method 500 for activation of a hand-held electronic device in response to a change in capacitance of a proximity sensor. In step 510 of the method, a hand-held electronic device 10 is provided. Hand-held electronic device 10 can be any of the devices described or otherwise envisioned herein. For example, hand-held electronic device 10 may comprise a body handle or body portion 12, a motor 22, a user input 26, a controller 30 with processor 32, a user interface 40, and a proximity sensor 50 comprising a capacitor. The proximity sensor may optionally comprise, for example, a conductive connector 54 and a conductive component 56.

At step 520 of the method, the hand-held electronic device determines a baseline capacitance of the proximity sensor. The proximity sensor generates an electric field, some of which finds ground and some of which leaks into areas around the capacitor and the hand-held electronic device. The characteristics of the generated electric field create a baseline capacitance that can be measured. The proximity sensor or controller 30 can establish this measured capacitance as the baseline capacitance against which future proximity sensor data is measured. For example, the proximity sensor may continuously or periodically obtain sensor data, and this obtained sensor data can then be compared to the baseline capacitance.

At step 530 of the method, the proximity sensor 50 detects a target object 52 approaching the handle of hand-held electronic device, before the target object actually touches the hand-held electronic device. According to an embodiment, as shown in FIG. 4, the approaching target object changes the capacitance of the proximity sensor to a first capacitance.

At step 540 of the method, the proximity sensor 50 and/or controller 30 compares the first capacitance to the baseline capacitance. If the first capacitance is different from the baseline capacitance, the system may determine that a target object is reaching for the hand-held electronic device, and that the device should be activated.

At optional step 542 of the method, the proximity sensor 50 and/or controller 30 compares the first capacitance to a predetermined activation threshold. If the threshold is met or exceeded, the system will proceed to activate the device. If the threshold is not met or exceeded, the system will not activate the device. According to an embodiment, the threshold may be automatically modified based on the baseline capacitance. For example, in some scenarios the baseline capacitance may increase or decrease, which will affect the difference between the baseline and the threshold. Accordingly, the activation threshold may be increased or decreased by an amount equivalent to the baseline threshold.

At step 550 of the method, the proximity sensor 50 and/or controller 30 sends a signal to activate the personal care hand-held electronic device 10 in response to the approaching target object. Activation may manifest, for example, in activation of the user interface 40, readiness of the device to engage in a care session, or in one or more other ways. Preferably, the hand-held electronic device is activated before the user touches the hand-held electronic device.

To prevent inadvertent activation of the hand-held electronic device 10, including in situations where a conductive object other than target object 52 approaches or is situated nearby the hand-held electronic device, the system optionally comprises a calibration protocol that periodically recalibrates the baseline capacitance. According to an embodiment, at optional step 522 of the method, the proximity sensor 50 can periodically obtain a new baseline capacitance as long as the device is not activated. For example, the proximity sensor 50 can obtain a new baseline capacitance every 30 seconds, although many other time periods are possible. The proximity sensor 50 and/or controller 30 receives the new measurement every 30 seconds resets the baseline capacitance with the new amount, unless the new measurement is significantly different due to the approach of target object 52.

At optional step 560 of the method, the calibration protocol is deactivated if the hand-held electronic device is active. As described in step 522 of the method, the system optionally comprises a calibration protocol that periodically recalibrates the baseline capacitance. This calibration protocol is deactivated if the hand-held electronic device is active, as the system assumes that the user is holding the device and that a baseline capacitance is not necessary. The calibration protocol can be reactivated once the device is deactivated.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of or “exactly one of,” or, when used in the claims, “consisting of” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of”

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of and “consisting essentially of shall be closed or semi-closed transitional phrases, respectively.

While several inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

1. A method for activating a hand-held electronic device, the method comprising the steps of:
providing a hand-held electronic device comprising a body portion and a proximity sensor, wherein the proximity sensor comprises a capacitor;
determining via the capacitor, a baseline capacitance of the proximity sensor;
detecting, via the capacitor, an approaching target object before the target object touches the body portion, wherein the approaching target object increases capacitance of the proximity sensor to a first capacitance;
comparing the first capacitance to the baseline capacitance; and
activating the hand-held electronic device if the first capacitance exceeds the baseline capacitance, wherein the hand-held electronic device is activated before the target object touches the hand-held electronic device.

2. The method of claim 1, wherein the proximity sensor comprises a conductive component configured to increase a sensitivity of the proximity sensor.

3. The method of claim 2, wherein the conductive component is a metal frame of the hand-held electronic device.

4. The method of claim 2, wherein the conductive component is an antenna of the hand-held electronic device.

5. The method of claim 2, wherein the proximity sensor comprises a conductive connector configured to electrically connect a capacitor sensor to the conductive component.

6. (canceled)

7. The method of claim 1, further comprising the step of calibrating, after a predetermined period of time, the proximity sensor with a new baseline capacitance.

8. The method of claim 1, further comprising the step of deactivating a calibration protocol if the hand-held electronic device is active.

9. The method of claim 1, further comprising the step of comparing the first capacitance to a predetermined threshold, wherein the hand-held electronic device is activated only if the first capacitance exceeds the predetermined threshold.

10. An electronic device comprising:
a body portion comprising a proximity sensor, wherein the proximity sensor comprises a capacitor; and
a controller configured to: (i) determine, via the capacitor, a baseline capacitance of the proximity sensor; (ii) detect, via the capacitor, an approaching target object before the target object touches the body portion, wherein the approaching target object increases capacitance of the proximity sensor to a first capacitance; (iii) compare the first capacitance to the baseline capacitance; and (iv) activate the electronic device if the first capacitance exceeds the baseline capacitance, wherein the electronic device is activated before the target object touches the electronic device.

11. The electronic device of claim 10, wherein the proximity sensor comprises a conductive component configured to increase a sensitivity of the proximity sensor.

12. The electronic device of claim 11, wherein the conductive component is a metal frame or antenna of the electronic device.

13. The electronic device of claim 11, wherein the proximity sensor comprises a conductive connector configured to electrically connect a capacitor sensor to the conductive component.

14. The electronic device of claim 10, wherein the body portion and the controller are contained within a hand-held portion.

15. A method for activating an electronic device, the method comprising the steps of:
providing an electronic device comprising a hand-held body portion and a proximity sensor, wherein the proximity sensor comprises a capacitor;
determining, via the capacitor, a baseline capacitance of the proximity sensor;
calibrating, after a predetermined period of time, the proximity sensor with a new baseline capacitance;
detecting, via the capacitor, an approaching target object before the target object touches the hand-held body portion, wherein the approaching target object increases capacitance of the proximity sensor to a first capacitance;
comparing the first capacitance to the baseline capacitance;
comparing the first capacitance to a predetermined threshold; and
activating the electronic device if the first capacitance exceeds the predetermined threshold, wherein the electronic device is activated before the target object touches the hand-held body portion of the electronic device.
